(19) United States
(12) Patent Application Publication
(10) Pub. No.: US 2004/0135163 A1
(43) Pub. Date: Jul. 15, 2004

(54) Pink light emitting diode

(76) Inventor: Hsing Chen, Jubei City (TW)

Correspondence Address: Keith Kline, PRO-TECHTOR INTERNATIONAL SERVICES, 20775 Norada Court, Saratoga, CA, 95070-3018, US

(21) Appl. No.: 10/705,381

(22) Filed: Nov. 10, 2003

(30) Foreign Application Priority Data
Jan. 13, 2003 (TW) 092100727

(51) Int. Cl. H01L 33/00

(52) U.S. Cl. 257/98

(57) ABSTRACT

A pink light emitting diode includes a blue LED chip and a mixing fluorescent powder. The mixing fluorescent powder, which includes a yellow fluorescent powder and a red fluorescent powder, is covered on the blue LED chip, wherein the yellow fluorescent powder is capable of absorbing a part of blue light emitted by blue LED chip and emitting yellow wavelength light, the red fluorescent powder is capable of absorbing a part of blue light emitted by blue LED chip and emitting red wavelength light, so that mixing the blue light, yellow light, and the red light to produce the pink light emitting diode.

### BACKGROUND OF THE INVENTION

1. Field of the invention

The present invention relates to a pink light emitting diode used in LED display, back light source, traffic signal, indicator, etc. and in particular to a pink light emitting diode comprising a blue LED chip and a mixing fluorescent powder, which converts the wavelength of light emitted by a blue LED chip and emitted light.

2. Description of the Related Art

The light emitting diode (LED) has the advantages of being electricity-saving, high reliability, recyclable, and safety. Thus it has been used widely in various applications such as indicators and light sources. Recently light emitting diode for RGB(red, green and blue) colors having ultra-high luminance and high efficiency have been developed, and large screen LED displays using these light emitting diode have been put into use. The LED display can be operated with less power and has such good characteristics as light weight and long life, and is therefore expected to be more widely use in the future.

Please referr to FIG. 1, is a traditional LED lamp including a blue LED chip 1, a lead frame 3, wires 4, a yellow fluorescent powder 8 and a compound layer 5. The blue LED chip 1 is mounted on the lead frame 3. The wires 4 are electrically connected the LED chip 1 to the lead frame 3. The yellow fluorescent powder 8 is coated on the LED chip 1. The compound layer 5 is encapsulanted in the LED chip 1 to finish the package of the LED.

A method of manufacturing LED is used various semiconductor materials to emit different color of light. A traditional method of manufacturing mixing light of light emitting diode, as white light, pink light, it is used at least two chips to emit different wavelength light, so as to mix various wavelength light to produces mixing light as white.

Further a traditional method of manufacturing mixing light of light emitting diode, is providing a fluorescent powder coated on the surface of LED chip, the fluorescent powder is capable of absorbing a part of light emitted by LED chip (as blue light et.) and emits light of a wavelength different from that of the absorbed light to produce another kind of color light. Mixing the emitted light and the absorbed light is to produce mixing light (as white light et.)

At present time, a mixing light is used to produce white light, which is providing a yellow fluorescent coated on the surface of a blue LED chip to emit yellow light. Mixing the yellow light and the blue light to produce white light. For example, the patent of a white light emitting diode (U.S. Pat. No. 5,998,925) of Nichia corpration. Please refer to FIG. 2, is schematically illustrated color coordinate of CIE of a white light emitting diode (U.S. Pat. No. 5,998,925) of Nichia corporation.

Furthermore, a method of manufacturing mixing light is to mix a red fluorescent powder, blue fluorescent powder, and green fluorescent powder coated on a purple LED chip with a wavelength ranging from 360 nm to 390 nm to produce white light or various kinds of color of light. For example, the patent of U.S. Pat. No. 5,952,684 of Solidlite corporation.

The method of manufacturing mixing light of Nichia corporation as above-mentioned. It dose not produce pink light emitting diode.

### SUMMARY OF THE INVENTION

The objective of the present invention is to provide a pink light emitting diode that is manufactured conveniently, the manufacturing processes is simplified and the manufacturing cost must be decreased.

The further objective of the present invention is to provide a pink light emitting diode with high luminance for a long period time.

To achieve the above-mentioned objective, the present invention includes a blue LED chip and a mixing fluorescent powder, which includes a yellow fluorescent powder and a red fluorescent powder, is covered on the blue LED chip, wherein the yellow fluorescent powder is capable of absorbing a part of blue light emitted by the blue LED chip and emitting yellow wavelength light, the red fluorescent powder is capable of absorbing a part of blue light emitted by blue LED chip and emitting red wavelength light, so that mixing the blue light, yellow light, and the red light to produce the pink light emitting diode.

According to one aspect of the present invention, a pink light emitting diode can be manufactured and the manufacturing cost must be decreased.

### BRIEF DESCRIPTION OF THE DRAWINGS

FIG. 1 is a schematic illustration showing a traditional LED lamp.

FIG. 2 is a schematic illustration showing a color coordinate of CIE of a white light emitting diode (U.S. Pat. No. 5,998,925) of Nichia corporation.

FIG. 3 is a schematic illustration showing a pin light emitting diode lamp of the present invention.

FIG. 4 is a schematic illustration showing a color coordinate of CIE of a pin light emitting diode of the present invention.

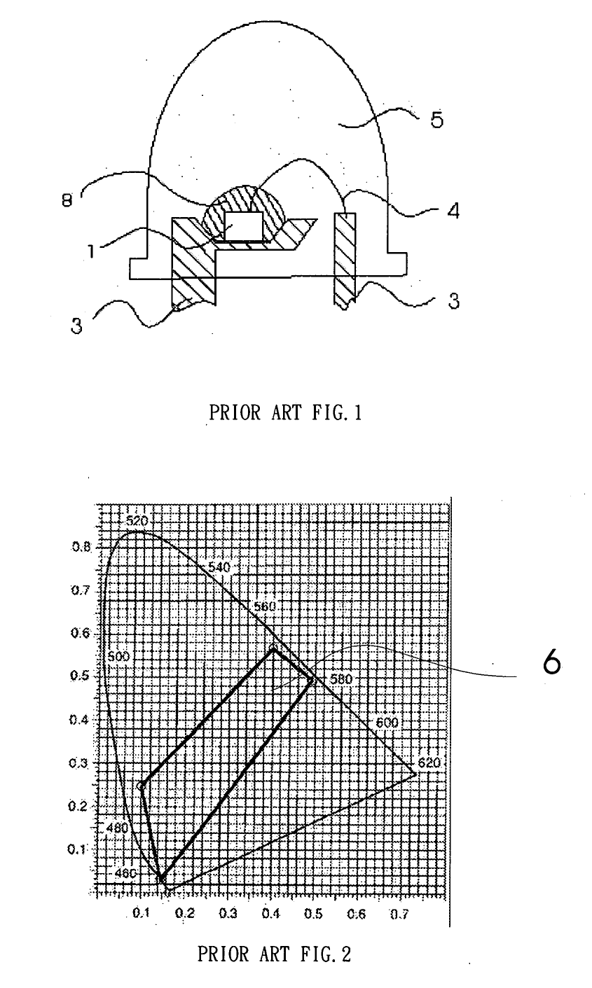

### DETAILED DESCRIPTION OF THE INVENTION

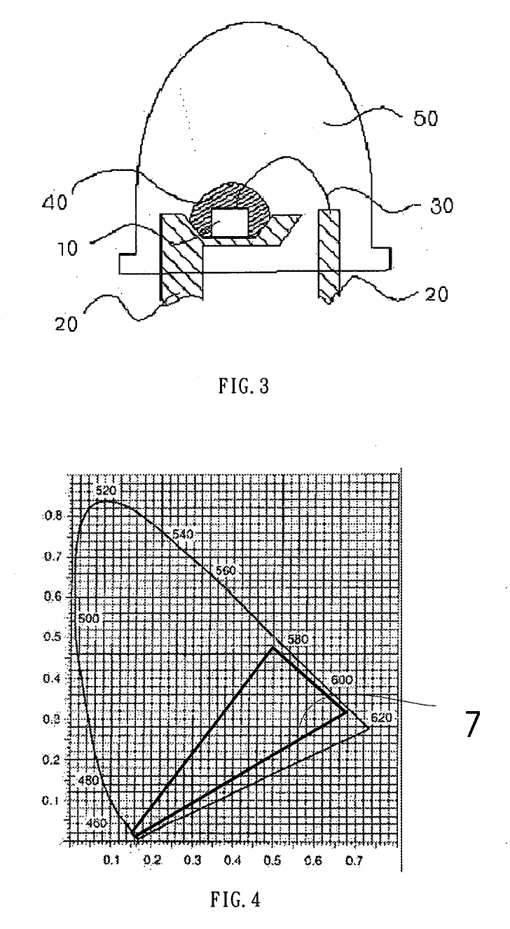

Please referr to FIG. 3, is a schematic illustration showing a pink light emitting diode lamp of the present invention includes a blue LED chip 10, a lead frame 20, wires 30, a mixing fluorescent powder 40, and a compound layer 50.

The blue LED chip 10 is the emitting source, which may be emitted blue light, the blue LED chip 10 is mounted on the lead frame 20. In the embodiment, the blue LED chip 10 has an emission light in a region of wavelength 425 nm to 455 nm.

The wires 30 are electrically connected the blue LED chip 10 to the lead frame 20 for transmitting the signals from the blue LED chip 10 to the lead frame 20. The mixing fluorescent powder 40, which includes a yellow fluorescent powder and a red fluorescent powder, is coated on the blue LED chip 10, wherein the yellow fluorescent powder is capable of absorbing a part of blue light emitted by blue LED chip and emitting yellow wavelength light, the red fluorescent powder is capable of absorbing a part of blue light emitted by blue LED chip and emitting red wavelength light, so that mixing the blue light, yellow light, and the red light to produce the pink light emitting diode.

In the embodiment, the red fluorescent powder has component of 6MgO•As₂O₅:Mn⁴⁺(Mg₆AS₂O₁₁:Mn)or 3.5MgO•0.5MgF₂•GeO₂Mn⁴⁺.

The yellow fluorescent powder has component of Y₃Al₅O₁₂Ce or (YGd)₃Al₅O₁₂:Ce.

Please refer to FIG. 4, wherein the region of the color coordinate from pink light emitting diode is to surround the coordinate of (0.155-0.03)-(0.165-0.2)-(0.68-0.32)-(0.5-0.48) of CIE.

The compound layer 50 is covered on the blue LED chip 10 to protect the blue LED chip 10 and wires 30.

The method of manufacturing of the above-mentioned, is providing a mixing fluorescent powder 40, which includes a yellow fluorescent powder and a red fluorescent powder, is coated on the blue LED chip 10, wherein the yellow fluorescent powder is capable of absorbing a part of blue light emitted by blue LED chip and emitting yellow wavelength light, the red fluorescent powder is capable of absorbing a part of blue light emitted by blue LED chip and emitting red wavelength light, so that mixing the blue light, yellow light, and the red light to produce the pink light emitting diode.

Therefore, the pink light emitting diode of the present invention has the following advantages.

1. Since the red fluorescent powder and yellow fluorescent powder are Oxide, so as to pink light emitting diode of the present invention has high stability in use, lower cost, and high luminance for a long period of time.

2. Since the manufacturing processes can be simplified, and the manufacturing costs also can be lowered.

While the invention has been described by way of an example and in terms of a preferred embodiment, it is to be understood that the invention is not limited to the disclosed embodiment. On the contrary, it is intended to cover various modifications. Therefore, the scope of the appended claims should be accorded the broadest interpretation so as to encompass all such modifications.

What is claimed is:

1. A pink light emitting diode, comprising:
a blue LED chip; and
a mixing fluorescent powder, which includes a yellow fluorescent powder and a red fluorescent powder, being covered on the blue LED chip, wherein the yellow fluorescent powder capable of absorbing a part of blue light emitted by blue LED chip and emitting yellow wavelength light, the red fluorescent powder capable of absorbing a part of blue light emitted by blue LED chip and emitting red emitting light, so that mixing the blue light, yellow light, and the red light to produce the pink light emitting diode.

2. A pink light emitting diode according to claim 1, wherein the blue light chip has an emission light in a region of wavelength 425 nm to 455 nm.

3. A pink light emitting diode according to claim 1, wherein the red fluorescent powder has component of Mg₆As₂O₁₁ :Mn or 3.5MgO•0.5MgF₂•GeO₂:Mn.

4. A pink light emitting diode according to claim 1, wherein the region of the color coordinate from pinK light emitting diode is to surround the coordinate of (0.1550.03)-(0.165-0.2)-(0.68-0.32)-(0.5-0.48) of CIE.

5. A pink light emitting diode according to claim 1, wherein the yellow fluorescent powder has component of Y₃Al₅O₁₂:Ce or (YGd)₃Al₅O₁₂:Ce.
